(19) United States
(12) Patent Application Publication
(10) Pub. No.: US 2012/0188082 A1
(43) Pub. Date: Jul. 26, 2012

(54) MERCHANDISE DISPLAY SECURITY DEVICE INCLUDING REMOVABLE AND MOVABLE CABLE COLLECTION TUBE

(75) Inventors: David N. Berglund, Charlotte, NC (US); Larry K. Hooks, JR., Fort Mills, SC (US); John F. Roberts, Charlotte, NC (US); Michael R. Johnston, Waxhaw, NC (US)

(73) Assignee: InVue Security Products Inc., Charlotte, NC (US)

(21) Appl. No.: 13/357,959

(22) Filed: Jan. 25, 2012

Related U.S. Application Data
(60) Provisional application No. 61/436,235, filed on Jan. 26, 2011.

(51) Int. Cl. G08B 13/12; H05K 5/02; F16L 3/08

(52) U.S. Cl. 340/568.2; 248/73; 312/223.1

(57) ABSTRACT

A merchandise display security device for displaying and protecting an article of merchandise includes a mounting element adapted to be mounted on a support surface with the mounting element defining an opening over a hole formed through the support surface. A base having a cable collection tube is configured to be received within the opening of the mounting element and passed through the hole to a location beneath the support surface. The base is releasably attached to the mounting element so that the base can be detached from the mounting element and the collection tube passed through the hole to provide access to the collection tube above the support surface. The collection tube may be movably disposed on the base so that the cable collection tube can be positioned at any desired angular location beneath the support surface relative to the base.

### CROSS REFERENCE To RELATED APPLICATION

This non-provisional application claims the benefit of U.S. Provisional Patent Application No. 61/436,235 filed on Jan. 26, 2011, the disclosure of which is incorporated herein in its entirety.

### FIELD OF THE INVENTION

This invention relates generally to merchandise display security systems for displaying and protecting an article of merchandise from theft. More particularly, the invention is a merchandise display security device including a removable and movable cable collection tube. In an exemplary embodiment, a merchandise display security device includes a mounting element and a base having a cable collection tube wherein the base is releasably attachable to and detachable from the mounting element so that the cable collection tube is removable from the mounting element. In another exemplary embodiment, the cable collection tube is movably disposed on the base so that the cable collection tube may be positioned at any desired orientation relative to the mounting element and the base.

### BACKGROUND OF THE INVENTION

Retailers routinely display handheld electronic merchandise, such as mobile (e.g. cellular) telephones, gaming consoles, personal data assistants (PDAs), global positioning system (GPS) devices, e-readers, tablets, media players, digital video recorders (DVRs), cameras and the like, for customers to examine before making a purchase. In some instances, the retailer desires the handheld electronic merchandise to be provided with electrical power so that a potential purchaser can evaluate the operation and features of the merchandise as well. At the same time, the retailer does not want the article of merchandise being displayed to be stolen or removed from the display by an unauthorized person. Accordingly, the article of merchandise is attached to a merchandise display security device that protects the article of merchandise from theft and unauthorized removal from the display. The merchandise display security device typically includes a sensor to which the article of merchandise is attached that indicates whether the article of merchandise has been separated (i.e. detached) from the sensor. In the event that the article of merchandise is detached from the sensor, an audible and/or visible alarm is activated to alert store personnel to a possible attempted theft or unauthorized removal of the merchandise from the display.

Merchandise display security systems for displaying and protecting an article of merchandise are known. Some of the known systems include a merchandise display security device that is mounted entirely above the support surface of the display, for example a display counter or shelf. Such “stand-alone” security devices typically include at least one electrical sense cord that extends between a base of the security device and a sensor that is removably supported on the base. The base is also commonly referred to as a display stand. Each stand-alone security device typically also includes at least one power cord that extends between and electrically connects the display stand and an external source of power, such as an electrical outlet or power transformer. The security devices may further include a power adapter cord, also commonly referred to as a pigtail, extending between and electrically connecting the sensor and the article of merchandise attached to the sensor. As a result, the multitude of cords of adjacent merchandise display security devices can become entangled with one another. Regardless, the excess cords detract from the aesthetics of the display and take up valuable counter or shelf space that could otherwise be utilized to display additional merchandise.

Other of the known merchandise display security systems include a security device that is partially mounted on the support surface of the display, for example on a display counter or shelf, above a closed cabinet or concealed enclosure. The remainder of the security device is located within the cabinet or enclosure so as to be inaccessible to customers, while remaining accessible to authorized personnel of the retail store for installation, removal, replacement or reconfiguration of the display. Placement of at least a portion of the merchandise display security devices within a cabinet or enclosure below the support surface of the display reduces the number of cords located above the support surface and restricts access to the vulnerable components of the security devices to authorized store personnel. However, the amount of available space beneath the support surface of the display is typically limited. As a result, it is oftentimes difficult, and consequently time consuming, for store personnel to assemble and disassemble the merchandise display security devices for installation, removal, replacement or reconfiguration of the display. Furthermore, the limited amount of space beneath the support surface of the display may prevent components of the security device located beneath the support surface from being positioned in a desirable orientation relative to components of the security device located above the support surface.

U.S. Pat. No. 7,744,404 B1 issued to Henson et al. and assigned to Merchandising Technologies, Inc. of Hillsboro, Oreg., USA discloses a merchandise display security system that includes a cable retraction mechanism for displaying merchandise mounted on a movable display post. The cable retraction mechanism includes a cable assembly and a coaxial housing having a movable shuttle that is coupled to one end of the cable assembly. The other end of the cable assembly is coupled to a sensor configured to be attached to a product to be displayed at the retail location. The cable assembly comprises an electrical cable having a coiled or otherwise elastic section. Reciprocating motion of the shuttle relative to the housing facilitates extension and retraction of the cable assembly independent of the extension and retraction, respectively, of the coiled or elastic section. The cable retraction mechanism has an internally threaded coupling that is secured on an externally threaded mounting element of a base or display stand beneath a support surface (e.g., display counter or shelf) at the retail location. As a result, the housing and the shuttle of the cable retraction mechanism cannot be accessed or removed from above the support surface of the display. Accordingly, it is both difficult and time consuming for authorized store personnel to install, remove, replace or reconfigure the display.

U.S. Pat. No. 7,724,135 B2 issued to Rapp et al. and assigned to Checkpoint Systems, Inc. of Thorofare, N.J., USA discloses another merchandise display security system for displaying an item (e.g. merchandise). The Rapp et al. system includes a tether having a first end and a second end that extends through a hole formed in a display shelf. The first end of the tether is secured to a mount for connection to the item above the display shelf and the second end is secured beneath the display shelf. A helical coil cable is wrapped around the tether and extends through the hole in the display shelf to provide an electrical path to the item from a cable reel and/or control unit located beneath the display shelf. The tether and helical coil cable are encased coaxially within an elongate, rigid housing that is secured to the underside of the display shelf. As such, the housing is not accessible or removable from above the display shelf. In addition, the rigid housing prevents the cable reel and/or control unit from being conveniently located at any desired orientation beneath the display shelf relative to the mount positioned above the display shelf.

Accordingly, there exists a need for an improved merchandise display security system for displaying and protecting an article of merchandise from theft. There exists a further, and more specific, need for a merchandise display security device including a removable and movable cable collection tube. There exists a particular need for a merchandise display security device including a mounting element and a base having a cable collection tube wherein the base is detachable from the mounting element so that the cable collection tube is removable from the mounting element. In this manner, the cable collection tube is removable and accessible from above a support surface of a display. There exists another particular need for a merchandise display security device including a mounting element and a base having a cable collection tube wherein the cable collection tube is movable relative to the base. In this manner, the cable collection tube may be located beneath a support surface of a display and positioned at any desirable orientation relative to the mounting element and the base located above the support surface of the display.

### BRIEF DESCRIPTION OF THE DRAWINGS

FIG. 1 is a perspective view of an exemplary embodiment of a merchandise display security device for displaying and protecting an article of merchandise according to the present invention showing a handheld electronic article of merchandise attached to the security device.

FIG. 2 is an elevation view of the merchandise display security device of FIG. 1 shown with the handheld electronic article of merchandise detached from the security device.

FIG. 3 is a perspective view of the mounting element of the merchandise display security device of FIG. 1 mounted over a hole formed through a support surface of a display.

FIG. 4 is a partial section view of the merchandise display security device of FIG. 1 shown with a base having a cable collection tube inserted in the hole formed through the support surface of the display and attached to the mounting element with the cable collection tube positioned beneath the support surface at a desirable orientation relative to the base and the mounting element.

FIG. 5 is an elevation view of the merchandise display security device shown with the mounting element of FIG. 3 mounted on the support surface of the display and the base having a cable collection tube being removed from the hole formed through the support surface of the display.

### DETAILED DESCRIPTION OF EXEMPLARY EMBODIMENTS

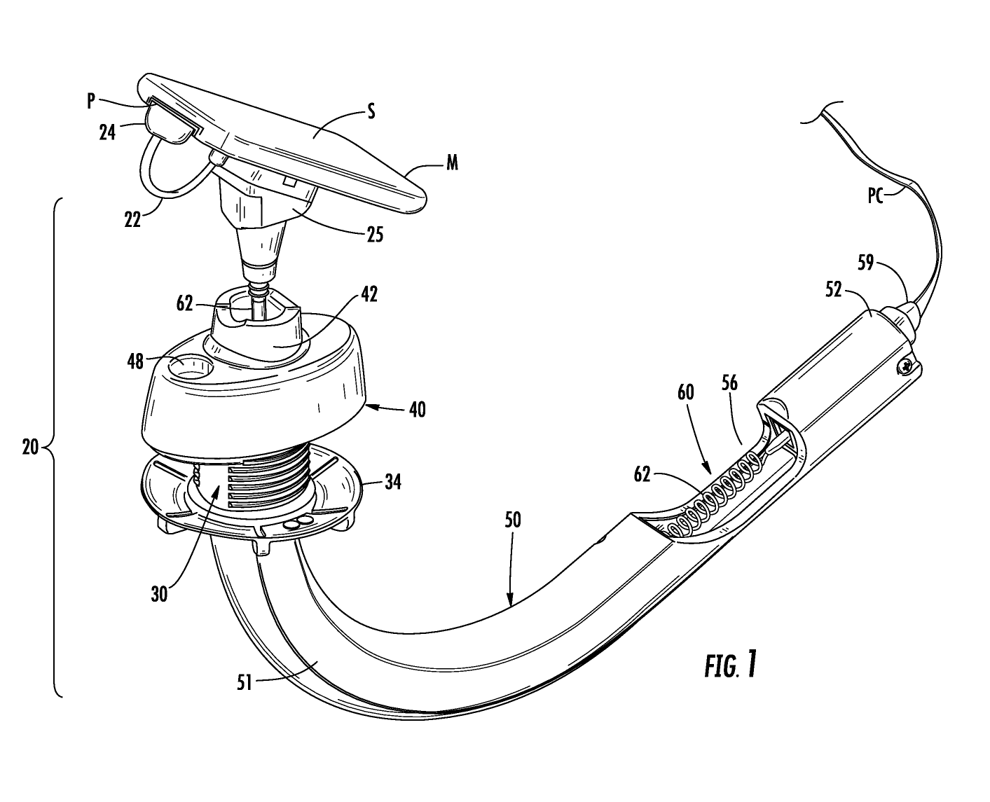

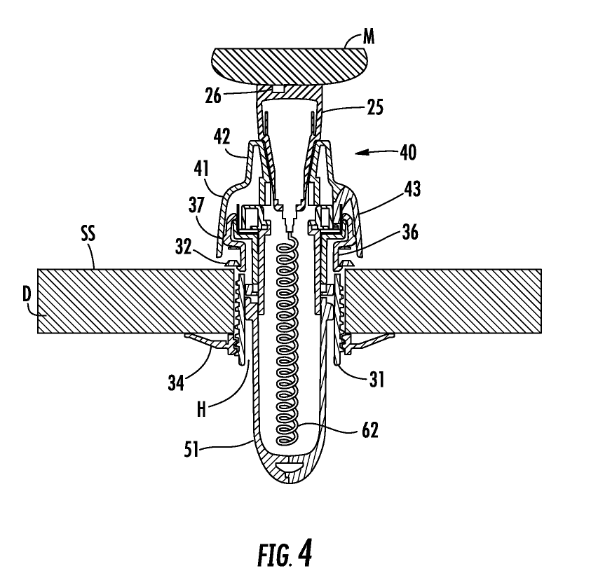

Referring now to the accompanying drawing figures wherein like reference numerals denote like elements throughout the various views, one or more exemplary embodiments of a merchandise display security system for displaying and protecting an article of merchandise are shown. More particularly, each exemplary embodiment is a merchandise display security device, indicated generally by reference character 20, for monitoring whether an article of merchandise, indicated generally by reference character M (FIG. 1 and FIG. 4), is attached to the security device. As shown and described herein, the merchandise display security device 20 includes electronics for monitoring a proximity sensor in contact with the article of merchandise M and for activating an alarm in the event that the article of merchandise is separated (i.e. detached) from the security device. If desired, a merchandise display security device 20 according to the invention may also provide electrical power to the article of merchandise M so that a potential purchaser may evaluate the merchandise in a powered state without relying solely on power provided by the internal battery of the merchandise. Thus, the present invention is equally applicable to any merchandise display stand, module, pedestal or the like that permits a potential purchaser to examine an article of merchandise in an unpowered state or to operate an article of merchandise in a powered state. An objective of the present invention is to provide a stand-alone merchandise display security device that reduces the number of cords located above a support surface of a display, such as a tabletop, counter, shelf or the like. Another objective of the present invention is to provide such a security device including a mounting element and a base having a cable collection tube disposed beneath the support surface of the display wherein the base can be detached from the mounting element so that cable collection tube can be removed and accessed from above the support surface. Still another objective of the present invention is to provide such a security device wherein the cable collection tube is movably mounted on the base so that the cable collection tube may be positioned beneath the support surface at a desired orientation relative to the mounting element and the base.

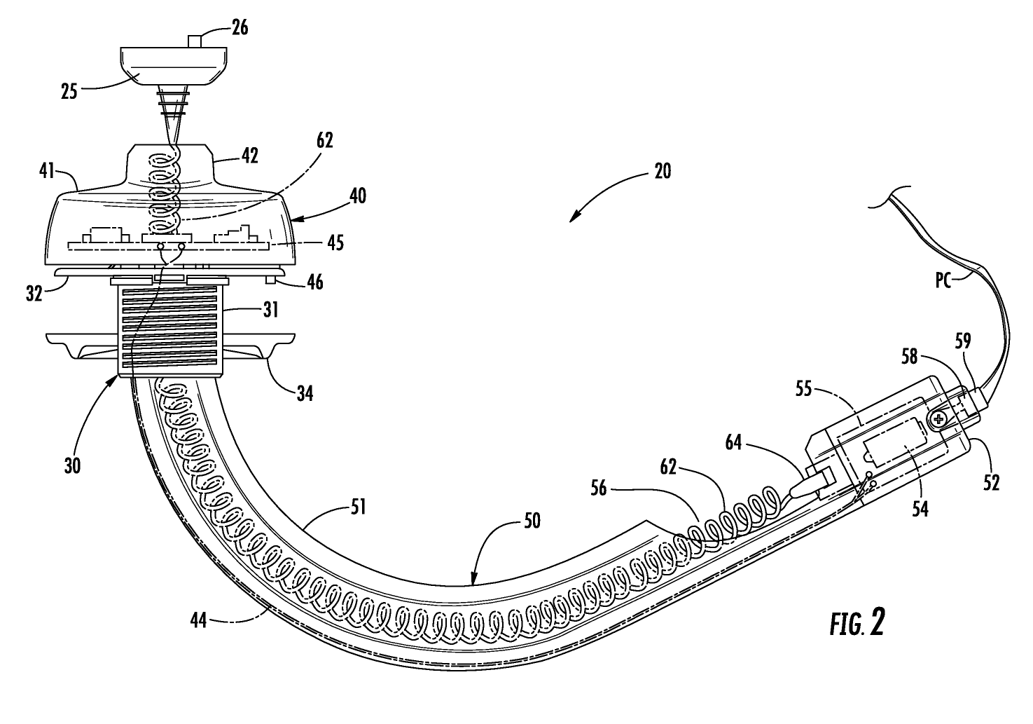

FIGS. 1 and 2 show a merchandise display security device 20 for displaying and protecting an article of merchandise M from theft or unauthorized removal from a display, for example a tabletop, counter, shelf or the like, located in a retail store. The article of merchandise M is typically a display model or sample of handheld electronic merchandise, such as a mobile (e.g. cellular) telephone, gaming console, personal data assistant (PDA), global positioning system (GPS) device, e-reader, tablet, media player, digital video recorder (DVR), handheld camera and the like, for customers to examine. The article of merchandise M is attached to the merchandise display security device 20 and may be displayed in a powered state so that potential purchasers are able to evaluate the operation and features of the merchandise when making a decision whether to purchase the item. In the exemplary embodiment shown in FIG. 1, the article of merchandise M is a conventional cellular type mobile telephone having a display screen S and a power input port P for receiving a power cord, for example an AC/DC transformer commonly referred to as a “charger,” electrically connected to an external power source. The power cord has a known type of electrical connector at one end configured for electrical connection to the power input port P. In the conventional example illustrated herein, the power input port P is a female jack configured to receive a male plug, such as a USB jack and complementary USB plug. In addition, the article of merchandise M may be provided with an internal battery that is recharged through the power cord by the external power source in a known manner.

As shown herein, the merchandise display security device 20 includes an optional power adapter cord 22 that replaces the conventional power cord to provide electrical power to the article of merchandise M while the merchandise is on display. The power adapter cord 22 has a connector plug 24 at one end configured to be received within a complementary connector jack at the power input port P of the cellular telephone. However, the present invention is intended to be construed broadly to include any type of standard or custom connector interface now known or hereafter devised. It is only necessary that the power adapter cord 22 has an appropriate interface at one end to electrically connect the power adapter cord to the article of merchandise M being displayed on the merchandise display security device 20. In the exemplary embodiments shown herein, the other end of the power adapter cord 22 is “hard-wired” directly into a sensor 25 to which the article of merchandise M is attached. Alternatively, the other end of the power adapter cord 22 may be provided with a connector interface (not shown) configured for electrically connecting the power adapter cord to the sensor 25 of the merchandise display security device 20. In this manner, the power adapter cord 22 may be easily and quickly disconnected and discarded or replaced with another power adapter cord appropriate for a different type or model of handheld electronic merchandise.

The merchandise display security device 20 comprises a mounting element 30 and a base 40 for removably supporting the sensor 25 and the article of merchandise M thereon in a display orientation. The base 40 has a cable collection tube 50 configured to receive, contain and retain therein a cable assembly 60 that electrically connects the sensor 25 and, consequently, the article of merchandise M, to an external power source through an optional power cord PC provided at a free end 52 of the cable collection tube. In the event it is not necessary or desired to provide electrical power to the article of merchandise M, the power cord PC may be omitted altogether since electrical power for the merchandise display security device 20 itself may be provided by an internal battery 54 (FIG. 2) disposed within the cable collection tube 60 as shown, or disposed within base 40. Alternatively, the merchandise display security device 20 and/or the article or merchandise M may be powered by the external power source through the power cord PC and the internal battery 54 omitted, or alternatively, retained for the purpose of providing back-up electrical power in the event of a power outage. Regardless, the cable assembly 60 comprises a length of an elastic or otherwise extensible electrical cable 62 that is contained within the cable collection tube 50 between the sensor 25 and an electrical circuit board (also referred to herein generically as “electronics”) 55 disposed adjacent the free end 52 of the cable collection tube. As shown herein, the cable 62 is a helical coil cable similar to a conventional telephone handset cord comprising an outer sheath made of an insulating material surrounding a plurality of conductors for a purpose to be described hereafter.

The configuration, and more particularly, the geometry of the cable collection tube 50 permits the cable 62 to be extended therefrom and retracted therein without kinking and without causing significant wear to the outer sheath. As such, the cable collection tube 50 protects the cable 62 when the sensor 25 and the article of merchandise M are removed from the display orientation on a pedestal portion 42 of the base 40 by a potential purchaser to evaluate the operation and features of the merchandise. In particular, one end of the cable 62 comprises a connector 64 (FIG. 2), for example a modular (RJ) telephone plug, configured to electrically connect the conductors of the cable to the electronics 55 adjacent the free end 52 of the cable collection tube. As shown, the other end of the cable 62 is “hard-wired” into the sensor 25. However, if desired, the other end of the cable 62 may comprise a connector, for example likewise a modular (RJ) telephone plug, configured to electrically connect the conductors of the cable to electronics disposed within the sensor 25. In the latter instance, the cable assembly 60 may be replaced without the need to detach the article of merchandise M from the sensor 25 in the event that cable 62 fails or becomes damaged. As such, the cable collection tube 50 may have a partial opening, recess or cutout 56 formed therein adjacent the electronics 55 for providing access to disconnect the connector 64 of the cable 62.

As shown herein, the cable collection tube 50 comprises an elongate, substantially cylindrical, substantially rigid, arcuate body 51 that is generally hollow to form an internal cavity sized sufficiently to house at least a portion of the cable 62 and the connector 64 of the cable assembly 60. As previously mentioned, an internal battery 54 and electronics 55 are housed within the cable collection tube 50 adjacent free end 52. The cable collection tube 50 terminates at the free end 52 in a connector 58 that is configured to receive a mating connector 59 on the free end of the power cord PC from the external power source. As previously mentioned, a cutout 56 may be formed in the body 51 adjacent the electronics 55 to provide access to the connector 64 on the cable 62 of the cable assembly 60. As such, a connector (not shown), for example a modular (RJ) telephone jack, is provided on the body 51 of the cable collection tube 50 or the circuit board 55 for receiving the connector 64 on the cable 62 of the cable assembly 60. At the opposite end of the cable collection tube 50, the body 51 is movably mounted on the base 40. More particularly, the body 51 of the cable collection tube 50 is rotatably mounted on the base 40 so that the cable collection tube may be positioned at any desired angular location about the base along a circumference defined by the radial distance between the central location at which the cable collection tube is attached to the base and the free end 52 of the body of the cable collection tube. If desired, the base 40 and/or the body 51 of the cable collection tube 50 may be provided with a mechanical stop to limit rotation of the cable collection tube relative to the base within a predetermined total amount of rotation, for example about three hundred fifty-five degrees) (355°), so that the cable assembly 60 and/or the power cord PC does not become excessively twisted.

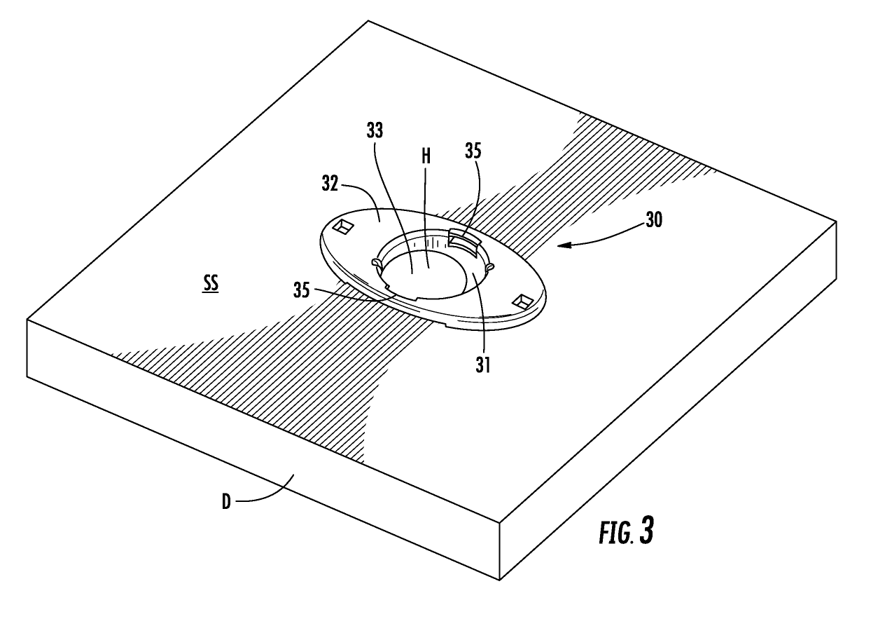

The mounting element 30 comprises a generally cylindrical, hollow body 31 (FIG. 2) having a mounting flange 32 at an upper end. The body 31 of the mounting element 30 is sized and shaped to receive the cable collection tube 50 coaxially within an opening 33 formed through the body and the mounting flange 32 of the mounting element. Body 31 is externally-threaded to receive an internally-threaded retaining flange 34 that secures the mounting element 30 on a support surface, such as a tabletop, counter, shelf or the like, of a display located in a retail store. As will be described in greater detail with reference to FIG. 3, the mounting element 30 is adapted to be inserted within a hole formed through a support surface of a display and to be secured thereon by mounting flange 32 and retaining flange 34 with the mounting flange of the mounting element configured to engage and releasably retain the base 40 in a desired display orientation above the support surface.

The base 40 comprises a body 41 having an upwardly extending pedestal portion 42 for removably supporting the sensor 25 and the article of merchandise M in the desired display orientation above the support surface. If desired, the pedestal portion 42 and the sensor 25 may be formed with opposing geometry, or alternatively, provided with one or more magnets for aligning the sensor and the article of merchandise M in the desired display orientation. The body 41 of the base 40 is generally hollow and defines an internal compartment sized sufficiently to pass the cable 62 of the cable assembly 60 therethrough, and to house an electrical circuit board (also referred to herein generically as “electronics”) 45. Electronics 45 are electrically connected to electronics 55 by an electrical cable or conduit 44 (FIG. 2) comprising at least a pair of conductors. Electrical cable or conduit 44 may be disposed on the inside or the outside of the body 51 of the collection tube 50, but more preferably, is disposed within the body of the collection tube to protect the conductors extending between electronics 45 and electronics 55. As previously mentioned, electronics 55 are electrically connected to the sensor 25 by conductors disposed within cable 62. As such, electronics 45 may operate to monitor the state of a sensor switch 26 (FIG. 2), for example a conventional proximity or limit switch, provided on the sensor 25 through cable 62 and electronics 55 to activate an audible and/or visible alarm in the event that article of merchandise M is separated from the sensor. As shown, base 40 further comprises a sensor switch 46, for example a conventional proximity or limit switch, provided on the underside of body 41 that extends through an aperture formed in the mounting flange 32 of the mounting element 30 when the base is engaged with the mounting element. Sensor switch 46 is electrically connected to electronics 45, which operate to monitor the state of the switch and to activate an audible and/or visible alarm in the event that base 40 is separated from the support surface of the display. Base 40 may also comprise a communication port 48 (FIG. 1) for permitting communication with electronics 45 to arm and disarm the alarm so that an authorized person can separate (i.e. detach) the article of merchandise M from the sensor 25, or separate (i.e. remove) the base and the cable collection tube 50 from the support surface of the display, as will be described hereafter.

FIG. 3 shows the mounting flange 32 of the mounting element 30 mounted on a support surface SS, for example a tabletop, counter, shelf or the like, of a display D located in a retail store. The mounting element 30 defines an opening 33 through the mounting flange 32 and is mounted on the support surface SS of the display D such that the opening is disposed over a hole H formed through the support surface with the body 31 of the mounting element extending downwardly through the hole. FIG. 4 is a partial section view showing the base 40 having cable collection tube 50 installed thereon with sensor 25 and cable assembly 60 disposed within the base and the collection tube. Base 40, along with collection tube 50, sensor 25 and cable assembly 60, is disposed through hole H formed in support surface SS of display D. As will be readily understood and appreciated by those skilled in the art, cable assembly 60 and sensor 25 are previously installed into base 40 and cable collection tube 50 by feeding the connector 64 of the cable assembly downwardly through the generally hollow body 41 of the base and the generally hollow body 51 of the cable collection tube and thereafter electrically connecting connector 64 to electronics 55. If utilized, the power cord PC may be electrically connected to the electronics 55 of the cable collection tube 50 via connector jack 58 and connector plug 59 before or after the base 40, cable collection tube 50, sensor 25 and cable assembly 60 are inserted through the hole H in the support surface SS. If power cord PC is connected afterwards, authorized store personnel would have to access the connector jack 58 at the free end 52 of the cable collection tube 50 beneath the support surface SS only upon initial installation of the merchandise display security device 20. Thereafter, the connector jack 58 could be accessed by removing the base 40 and collection tube 50 through the hole H in support surface SS of display D. Retaining flange 34 is threaded onto body 31 of mounting element 30 from beneath the support surface SS of the display D to secure the mounting flange 32 against the support surface with the body of the mounting element extending downwardly through the hole H.

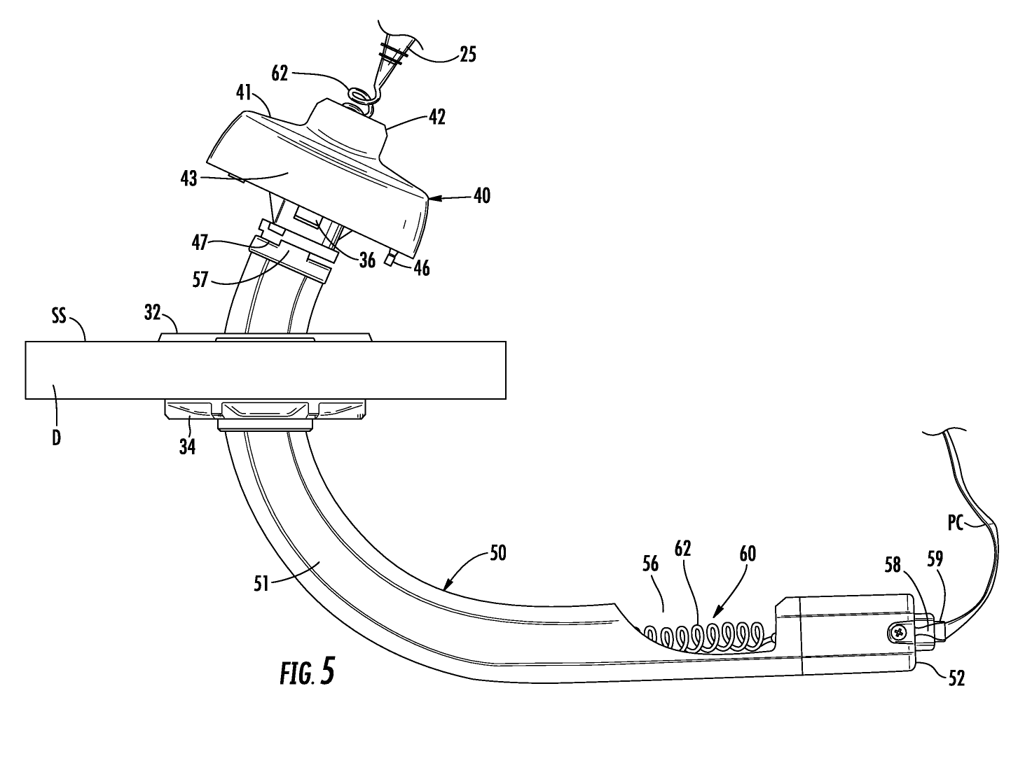

As best shown in FIG. 3, mounting flange 32 is provided with a pair of circumferentially spaced, laterally opposed recesses 35 for receiving resilient engaging features provided on the base 40. As best shown in FIG. 4, base 40 comprises a pair of laterally opposed resilient locking legs 36 for engaging the recesses 35 formed in the mounting flange 32. Each locking leg 36 depends in a cantilever fashion from the base 40 and is provided with a protrusion 37 that rests against the inner surface of the body 41 of the base in a relaxed, or unbiased, position. The body 41 of base 40, and more particularly, opposite sidewalls 43 of the base are sufficiently elastic and deformable such that a force flexing the sidewalls inwardly causes the locking legs 36 to move from an unbiased position in engagement with the mounting flange 32 to a biased position out of engagement with the mounting flange. As illustrated in FIG. 5, base 40 and cable collection tube 50 with sensor 25 and cable assembly 60 contained therein may be withdrawn through the hole H formed in the support surface SS of display D. In this manner, the base 40, cable collection tube 50, sensor 25 and cable assembly 60 of the merchandise display security device 20 may be readily removed from the mounting element 30 after installation and accessed from above the support surface SS of the display D for repair or replacement. Furthermore, the same or a different merchandise display security device 20 (except for the mounting element 30) may be installed at the same location on the support surface SS of the display D without the need to access any of the components from beneath the support surface. As will be readily understood and appreciated by those skilled in the art, connector plug 59 of power cord PC may be disconnected from connector jack 58 at the free end 52 of collection tube 50 and reconnected to the same or a different collection tube as long as the power cord has sufficient length to be withdraw through the hole H in the support surface SS of the display D. Thus, the merchandise display security device 20 of the present invention provides for rapid and easy interchangeability and reconfiguration of the merchandise display. Although recesses 35 on mounting element 30 and locking legs 36 on base 40 are shown and described herein for releasably attaching and detaching the base, it should be noted that any connection means suitable for removably attaching the base to the mounting element may be utilized without departing from the spirit and intended scope of the invention. For example, base 40 may be removably attached and releasably detached from the mounting element by a threaded mechanical connection, a bayonet type mechanical connection, tamper-proof mechanical fasteners, a ball and detent mechanical connection with or without a magnet and a magnetically attractable component, a vacuum fitting over the mounting element, or any other suitable releasable and removable connection.

As previously mentioned, the cable collection tube 50 is movably, and more preferably, rotatably coupled to the base 40. Furthermore, a mechanical stop 47, 57 (FIG. 5) may be provided on the base and the cable collection tube, respectively, to limit rotation of the cable collection tube relative to the body to, for example, about three hundred fifty-five degrees (355°) so that the cable assembly 60 is not twisted excessively absent a swivel, detangler or other component for reducing torsion forces applied to the cable 62. At the same time, the cable collection tube 50 may be positioned beneath the support surface SS of the display D at any desired angular location relative to the mounting element 30 and the base 40. In this manner, a plurality of the merchandise display security devices 20 may be installed utilizing the available space beneath the support surface SS in an economical fashion, thereby maximizing the number of security devices on the display D. It should be further noted that the body 51 of the cable collection tube 50 is intentionally formed with an arcuate shape that both limits the amount of vertical space beneath the support surface required for installation of the merchandise display security device 20 and facilitates insertion and removal of the cable collection tube through the mounting element 30 disposed within the hole H of the display D.

The foregoing has described one or more exemplary embodiments of a merchandise display security device for displaying and protecting an article of merchandise on a support surface, for example a tabletop, counter, shelf or the like, of a display located in a retail store. The merchandise display security device includes a mounting element and a base having a movable cable collection tube that is releasably attachable to and detachable from the mounting element. The base is detached from the mounting element so that the cable collection tube, along with a sensor and a cable assembly electrically connected to the base through the cable collection tube, is removable and accessible from above the support surface of the display. As a result, the cable assembly may be repaired or replaced, or alternatively, the base, cable collection tube, sensor and cable assembly may be removed to reconfigure the display after initial installation without the need for authorized store personnel to access the merchandise display security device from beneath the support surface. Furthermore, the cable collection tube is movably disposed on the base so that the cable collection tube may be positioned beneath the support surface of the display at any desired angular location relative to the mounting element and the base.

Exemplary embodiments of a merchandise display security device including at least the aforementioned features have been shown and described herein for purposes of illustrating and enabling the best mode of the invention. Those of ordinary skill in the art, however, will readily understand and appreciate that numerous variations and modifications of the invention may be made without departing from the spirit and scope of the invention. Accordingly, all such variations and modifications are intended to be encompassed by the appended claims.

That which is claimed is:

1. A merchandise display security device for displaying and protecting an article of merchandise comprising:
a mounting element adapted to be mounted on a support surface with the mounting element defining an opening over a hole formed through the support surface; and
a base having a cable collection tube configured to be received within the opening of the mounting element and passed through the hole of the support surface to a location beneath the support surface, the base being releasably attached to the mounting element so that the base can be detached from the mounting element and the collection tube passed through the hole of the support surface from the location beneath the support surface so as to provide access to the collection tube above the support surface.

2. A security device according to claim 1, wherein the collection tube comprises a generally hollow body for receiving a cable assembly that extends between a sensor configured to be removably supported on the base and a free end of the collection tube.

3. A security device according to claim 2, wherein the cable assembly comprises an elastic cable containing at least a pair of conductors that electrically connect the cable assembly to the sensor and wherein the cable is extensible and retractable relative to the collection tube.

4. A security device according to claim 3, wherein the cable is a helical coil cable.

5. A security device according to claim 3, wherein the conductors of the cable electrically connect the cable assembly to electronics disposed within the collection tube.

6. A security device according to claim 5, wherein the base comprises a generally hollow body for housing electronics and wherein an electrical conduit containing at least a pair of conductors extends between the base and the collection tube to electrically connect the electronics housed within the base with the electronics disposed within the collection tube.

7. A security device according to claim 6, wherein the sensor comprises a sensor switch for engaging the article of merchandise that is electrically connected to the conductors of the cable of the cable assembly so that the sensor switch is electrically connected to the electronics disposed within the collection tube through the cable assembly and is electrically connected to the electronics housed within the base through the conductors of the electrical conduit.

8. A security device according to claim 7, wherein at least one of the electronics housed within the base and the electronics disposed within the collection tube activates an alarm if the sensor switch of the sensor is armed and the article of merchandise is separated from the sensor.

9. A security device according to claim 7, wherein the base comprises a sensor switch for engaging the support surface that is electrically connected to the electronics housed within the base and wherein at least one of the electronics housed within the base and the electronics disposed within the collection tube activates an alarm if the sensor switch of the base is armed and the base is separated from the support surface.

10. A security device according to claim 1, wherein the base comprises at least one resilient locking leg and wherein the mounting element has at least one recess for engaging the locking leg of the base to releasably attach the base to the mounting element.

11. A merchandise display security device for displaying and protecting an article of merchandise comprising:
a mounting element adapted to be mounted on a support surface with the mounting element defining an opening over a hole formed through the support surface; and
a base having a cable collection tube configured to be received within the opening of the mounting element and passed through the hole of the support surface to a location beneath the support surface, the collection tube being movably disposed on the base so that the cable collection tube can be positioned at any desired angular location beneath the support surface relative to the base.

12. A security device according to claim 11, wherein the collection tube comprises a generally hollow body for receiving a cable assembly that extends between a sensor configured to be removably supported on the base and a free end of the collection tube.

13. A security device according to claim 12, wherein the cable assembly comprises an extensible and retractable cable containing at least a pair of conductors that electrically connect the cable assembly to the sensor.

14. A security device according to claim 13, wherein the cable is a helical coil cable.

15. A security device according to claim 13, wherein the conductors of the cable electrically connect the cable assembly to electronics disposed within the collection tube.

16. A security device according to claim 15, wherein the base comprises a generally hollow body for housing electronics and wherein an electrical conduit containing at least a pair of conductors extends between the base and the collection tube to electrically connect the electronics housed within the base with the electronics disposed within the collection tube.

17. A security device according to claim 16, wherein the sensor comprises a sensor switch for engaging the article of merchandise that is electrically connected to the conductors of the cable of the cable assembly so that the sensor switch is electrically connected to the electronics disposed within the collection tube through the cable assembly and is electrically connected to the electronics housed within the base through the conductors of the electrical conduit.

18. A security device according to claim 17, wherein at least one of the electronics housed within the base and the electronics disposed within the collection tube activates an alarm if the sensor switch of the sensor is armed and the article of merchandise is separated from the sensor.

19. A security device according to claim 17, wherein the base comprises a sensor switch for engaging the support surface that is electrically connected to the electronics housed within the base, and wherein at least one of the electronics housed within the base and the electronics disposed within the collection tube activates an alarm if the sensor switch of the base is armed and the base is separated from the support surface.

20. A security device according to claim 11, wherein the base comprises at least one resilient locking leg and wherein the mounting element has at least one recess for engaging the locking leg of the base to releasably attach the base to the mounting element.
